(19) United States
(12) Patent Application Publication
(10) Pub. No.: US 2026/0304649 A1
(43) Pub. Date: Oct. 1, 2026

(54) Backing Layers for Flexible Displays

(71) Applicant: Apple Inc., Cupertino, CA (US)

(72) Inventors: Tyler R Kakuda, Palo Alto, CA (US); Christopher D Jones, Los Gatos, CA (US); Benjamin J Kallman, Emerald Hills, CA (US); Paul C Kelley, San Francisco, CA (US); Justin Memar-Makhsous, Cupertino, CA (US); Benjamin J Pope, Woodside, CA (US); Matthew P Rao, Massapequa Park, NY (US); Ying-Chih Wang, Sunnyvale, CA (US); James R Wilson, Saratoga, CA (US); Shaorui Yang, San Jose, CA (US); Deokkyun Yoon, Milpitas, CA (US); Chen Zhong, Yangzhou (CN)

(21) Appl. No.: 19/574,138

(22) Filed: Mar. 20, 2026

Related U.S. Application Data
(60) Provisional application No. 63/781,874, filed on Apr. 1, 2025.
(60) Provisional application No. 63/813,488, filed on May 28, 2025.

(51) Int. Cl. H05K 5/02; H05K 5/03

(52) U.S. Cl. CPC H05K 5/0217; H05K 5/03

(57) ABSTRACT

An electronic device may include a flexible display and a foldable housing. The display may include a foldable cover glass, an array of pixels configured to display images through the foldable cover glass, and a backing layer configured to support the array of pixels. The backing layer may have an elastic modulus ranging from 50 GPa to 300 GPa and may be formed from glass or other suitable materials. The backing layer may have a higher stiffness in non-bending regions of the display and a lower stiffness in a bend region of the display. The variation in stiffness may be achieved using different thicknesses, different materials, different embedded structures, or different carbon fiber weaves. A glass backing layer may have a chamfered edge covered by a coating that is trimmed to align with other layers such as a metal backplate.

This application claims the benefit of U.S. provisional patent application No. 63/813,488, filed May 28, 2025, and U.S. provisional patent application No. 63/781,874, filed Apr. 1, 2025, both of which are hereby incorporated by reference herein in their entireties.

### FIELD

This relates generally to electronic devices and, more particularly, to electronic devices with displays.

### BACKGROUND

Electronic devices often have displays. Portability may be a concern for some devices, which tends to limit available real estate for displays.

### SUMMARY

An electronic device may include a flexible display having first and second display portions that rotate relative to one another about a bend axis. The flexible display may be mounted to a foldable housing having first and second housing portions coupled by a hinge that overlaps the bend axis. The foldable housing may be operable in a flat (e.g., open) state and a folded (e.g., closed) state.

The display may include a foldable cover glass, an array of pixels configured to display images through the foldable cover glass, and a backing layer configured to support the array of pixels. The backing layer may have an elastic modulus ranging from 50 GPa to 300 GPa and may be formed from glass or other suitable materials. The backing layer may have a higher stiffness in non-bending regions of the display and a lower stiffness in a bend region of the display. The variation in stiffness may be achieved using different thicknesses, different materials, different embedded structures, or different carbon fiber weaves.

A glass backing layer may have a chamfered edge covered by a coating that is trimmed to align with other layers such as a metal backplate. The glass backing layer may have local variations in compressive strength resulting from localized ion exchange at the outer perimeter of the glass backing layer.

### BRIEF DESCRIPTION OF THE DRAWINGS

FIG. 1 is a schematic diagram of an illustrative electronic device in accordance with some embodiments.

FIG. 2 is a perspective view of an illustrative electronic device with a display in accordance with some embodiments.

FIG. 3 is a side view of an illustrative electronic device in accordance with some embodiments.

FIG. 4 is a side view of an illustrative electronic device having a cover glass, a pixel array, a backing layer, and a backplate in accordance with some embodiments.

FIG. 5 is a side view of an illustrative electronic device having a backing layer with a chamfered edge covered by a coating that is trimmed to align with a backplate in accordance with some embodiments.

FIG. 6 is a side view of an illustrative electronic device having a backing layer and a cover glass with peripheral edges that are covered by coatings in accordance with some embodiments.

FIG. 7 is a side view of an illustrative electronic device having a backing layer and a cover glass with peripheral edges that are covered by coatings and that are coupled by an intervening support structure in accordance with some embodiments.

FIG. 8 is a top view of a backing layer that has a light transmitting window in accordance with some embodiments.

FIG. 9 is a side view of a backing layer having glass fibers embedded in a first polymer in non-bending regions and a second polymer in a bend region in accordance with some embodiments.

FIG. 10 is a top view of a backing layer having carbon fibers with a first weave in non-bending regions and a second weave in a bend region in accordance with some embodiments.

FIG. 11 is a top view of a backing layer having slits in a bend region in accordance with some embodiments.

FIG. 12 is a side view of a backing layer having pillars embedded in a polymer in non-bending regions in accordance with some embodiments.

FIG. 13 is a side view of an illustrative electronic device having a cover layer, an array of pixels, and a backing layer that replaces a backplate in accordance with some embodiments.

FIG. 14 is a side view of an illustrative glass backing layer having glass portions in a bend region that are separated by gaps filled with polymer material in accordance with some embodiments.

FIG. 15 is a side view of an illustrative glass backing layer having multiple glass layers and a polymer filler material in accordance with some embodiments.

### DETAILED DESCRIPTION

Electronic devices may be provided with displays. Displays may be used for displaying images for users. Displays may be formed from arrays of light-emitting diode pixels or other pixels. For example, a device may have an organic light-emitting diode display or a display formed from an array of micro-light-emitting diodes (e.g., diodes formed from crystalline semiconductor dies).

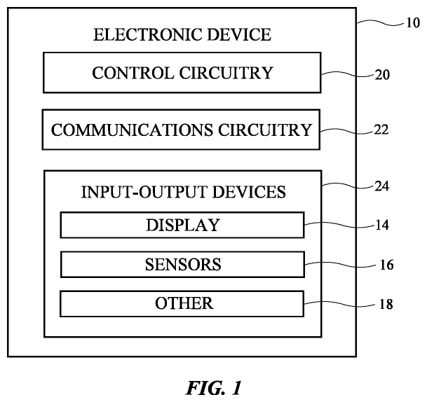

A schematic diagram of an illustrative electronic device having a display is shown in FIG. 1. Device 10 may be a cellular telephone, tablet computer, laptop computer, wristwatch device or other wearable device, a television, a stand-alone computer display or other monitor, a computer display with an embedded computer (e.g., a desktop computer), a system embedded in a vehicle, kiosk, or other embedded electronic device, a media player, or other electronic equipment. Configurations in which device 10 is a cellular telephone, tablet computer, or other portable electronic device may sometimes be described herein as an example. This is illustrative. Device 10 may, in general, be any suitable electronic device with a display.

Device 10 may include control circuitry 20. Control circuitry 20 may include storage and processing circuitry for supporting the operation of device 10. The storage and processing circuitry may include storage such as nonvolatile memory (e.g., flash memory or other electrically-programmable-read-only memory configured to form a solid state drive), volatile memory (e.g., static or dynamic random-access-memory), etc. Processing circuitry in control circuitry 20 may be used to gather input from sensors and other input devices and may be used to control output devices. The processing circuitry may be based on one or more microprocessors, microcontrollers, digital signal processors, baseband processors and other wireless communications circuits, power management units, audio chips, application specific integrated circuits, etc. During operation, control circuitry 20 may use a display and other output devices in providing a user with visual output and other output.

To support communications between device 10 and external equipment, control circuitry 20 may communicate using communications circuitry 22. Circuitry 22 may include antennas, radio-frequency transceiver circuitry (wireless transceiver circuitry), and other wireless communications circuitry and/or wired communications circuitry. Circuitry 22, which may sometimes be referred to as control circuitry and/or control and communications circuitry, may support bidirectional wireless communications between device 10 and external equipment over a wireless link (e.g., circuitry 22 may include radio-frequency transceiver circuitry such as wireless local area network transceiver circuitry configured to support communications over a wireless local area network link, near-field communications transceiver circuitry configured to support communications over a near-field communications link, cellular telephone transceiver circuitry configured to support communications over a cellular telephone link, or transceiver circuitry configured to support communications over any other suitable wired or wireless communications link). Wireless communications may, for example, be supported over a Bluetooth® link, a WiFi® link, a wireless link operating at a frequency between 6 GHz and 300 GHz, a 60 GHz link, or other millimeter wave link, cellular telephone link, wireless local area network link, personal area network communications link, or other wireless communications link. Device 10 may, if desired, include power circuits for transmitting and/or receiving wired and/or wireless power and may include batteries or other energy storage devices. For example, device 10 may include a coil and rectifier to receive wireless power that is provided to circuitry in device 10.

Device 10 may include input-output devices such as devices 24. Input-output devices 24 may be used in gathering user input, in gathering information on the environment surrounding the user, and/or in providing a user with output. Devices 24 may include one or more displays such as display 14. Display 14 may be an organic light-emitting diode display, a liquid crystal display, an electrophoretic display, an electrowetting display, a plasma display, a microelectromechanical systems display, a display having a pixel array formed from crystalline semiconductor light-emitting diode dies (sometimes referred to as microLEDs), and/or other display. Configurations in which display 14 is an organic light-emitting diode display or microLED display are sometimes described herein as an example.

Display 14 may have an array of pixels configured to display images for a user. The pixels may be formed as part of a display panel that is bendable. This allows device 10 to be folded and unfolded about a bend axis. For example, a flexible (bendable) display in device 10 may be folded so that device 10 may be placed in a compact shape for storage and may be unfolded when it is desired to view images on the display.

Sensors 16 in input-output devices 24 may include force sensors (e.g., strain gauges, capacitive force sensors, resistive force sensors, etc.), audio sensors such as microphones, touch and/or proximity sensors such as capacitive sensors (e.g., a two-dimensional capacitive touch sensor integrated into display 14, a two-dimensional capacitive touch sensor overlapping display 14, and/or a touch sensor that forms a button, trackpad, or other input device not associated with a display), and other sensors. If desired, sensors 16 may include optical sensors such as optical sensors that emit and detect light, ultrasonic sensors, optical touch sensors, optical proximity sensors, and/or other touch sensors and/or proximity sensors, monochromatic and color ambient light sensors, image sensors, fingerprint sensors, temperature sensors, sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices that capture three-dimensional images), optical sensors such as self-mixing sensors and light detection and ranging (lidar) sensors that gather time-of-flight measurements, humidity sensors, moisture sensors, gaze tracking sensors, and/or other sensors. In some arrangements, device 10 may use sensors 16 and/or other input-output devices to gather user input. For example, buttons may be used to gather button press input, touch sensors overlapping displays can be used for gathering user touch screen input, touch pads may be used in gathering touch input, microphones may be used for gathering audio input, accelerometers may be used in monitoring when a finger contacts an input surface and may therefore be used to gather finger press input, etc.

If desired, electronic device 10 may include additional components (see, e.g., other devices 18 in input-output devices 24). The additional components may include haptic output devices, audio output devices such as speakers, light-emitting diodes for status indicators, light sources such as light-emitting diodes that illuminate portions of a housing and/or display structure, other optical output devices, and/or other circuitry for gathering input and/or providing output. Device 10 may also include a battery or other energy storage device, connector ports for supporting wired communication with ancillary equipment and for receiving wired power, and other circuitry.

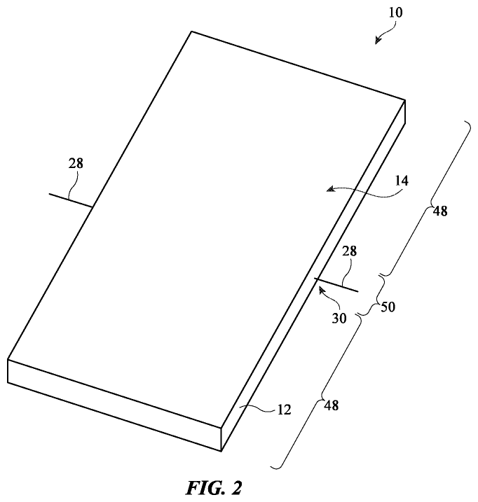

FIG. 2 is a perspective view of electronic device 10 in an illustrative configuration in which device 10 is a portable electronic device such as a cellular telephone or tablet computer. As shown in FIG. 2, device 10 may have a display such as display 14. Display 14 may cover some or all of the front face of device 10. Touch sensor circuitry such as two-dimensional capacitive touch sensor circuitry may be incorporated into display 14.

Display 14 may be mounted in housing 12. Housing 12 may form front and rear housing walls, sidewall structures, and/or internal supporting structures (e.g., a frame, an optional midplate member, etc.) for device 10. Glass structures, transparent polymer structures, and/or other transparent structures that cover display 14 and other portions of device 10 may provide structural support for device 10 and may sometimes be referred to as housing structures. For example, a transparent housing portion such as a glass or polymer housing structure that covers and protects a pixel array in display 14 may serve as a display cover layer for the pixel array while also serving as a housing wall on the front face of device 10. In configurations in which a display cover layer is formed from glass, the display cover layer may sometimes be referred to as a display cover glass or display cover glass layer. The portions of housing 12 on the sidewalls and rear wall of device 10 may be formed from glass or other transparent structures and/or opaque structures. Sidewalls and rear wall structures may be formed as extensions to the front portion of housing 12 (e.g., as integral portions of the display cover layer) and/or may include separate housing wall structures.

Device 10 may be a foldable electronic device that folds along one or more bend axes such as bend axis 28. In the example of FIG. 2, device 10 includes first and second portions 48 joined by bendable portion 50. Portions 48 of device 10 (e.g., portions 48 of display 14 and housing 12, sometimes referred to as the non-bending regions of device 10) may rotate relative to one another about axis 28. As one portion 48 rotates relative to another portion 48 (e.g., during folding and unfolding of device 10), bendable portion 50 of display 14 may bend and flex (e.g., while portions 48 remain flat).

Housing 12 may have flexible structures (e.g., bendable housing wall structures) and/or hinge structures such as hinge 30. Hinge 30 may have a hinge axis aligned with or offset relative to display bend axis 28, depending on the type of hinge used. Bend axis 28 may, for example, be the bend axis around which display 14 bends, whereas hinge 30 may bend about a hinge bend axis. In some arrangements such as teardrop hinge arrangements, the hinge bend axis of hinge 30 may be aligned with display bend axis 28 of display 14. In other arrangements such as constant length hinge arrangements (e.g., a roller hinge), the hinge bend axis may be offset from display bend axis 28. Device 10 may include one or more translation modules that facilitate translation of display 14 relative to housing 12 to accommodate the offset between display bend axis 28 and the hinge bend axis.

Hinge 30 and/or flexible housing structures that overlap bend axis 28 may allow housing 12 to bend about the hinge bend axis. For example, portion 48 of housing 12 may be located on one side of hinge 30 and another portion 48 of housing 12 may be located on the opposing side of bend hinge 30. Portions 48 of housing 12 may be configured to rotate relative to one another about hinge 30. Hinge 30 may be a roller hinge including one or more rollers each having a longitudinal axis that extends parallel to bend axis 28. This is merely illustrative. If desired, hinge 30 may include other types of hinge structures.

As housing 12 is bent about hinge 30, the flexibility of display 14 allows display 14 to bend about axis 28. In an illustrative configuration, housing 12 and display 14 may bend by 180°. This allows display 14 to be folded back on itself (e.g., such that first and second portions 48 of display 14 face each other). The ability to place device 10 in a folded configuration in this way may help make device 10 compact so that device 10 can be stored efficiently. When it is desired to view images on display 14, device 10 may be unfolded about axis 28 to place device 10 in the unfolded (e.g., flat) configuration of FIG. 2. This allows display 14 to lie flat and allows a user to view flat images on display 14. The ability to fold display 14 onto itself allows device 10 to exhibit an inwardly folding behavior. Display 14 may be sufficiently flexible to allow device 10 to be folded outwardly and/or inwardly, if desired.

Device 10 of FIG. 2 has a rectangular outline (rectangular periphery) with four corners. As shown in FIG. 2, a first pair of parallel edges (e.g., the left and right edges of device 10 in the example of FIG. 2) may be longer than a second pair of parallel edges (e.g., the upper and lower edges of device 10 of FIG. 2) that are oriented at right angles to the first pair of parallel edges. In this type of configuration, housing 12 is elongated along a longitudinal axis that is perpendicular to bend axis 28. Housing 12 may have other shapes, if desired (e.g., shapes in which housing 12 has a longitudinal axis that extends parallel to bend axis 28). With an arrangement of the type shown in FIG. 2, the length of device 10 along its longitudinal axis may be reduced by folding device 10 about axis 28.

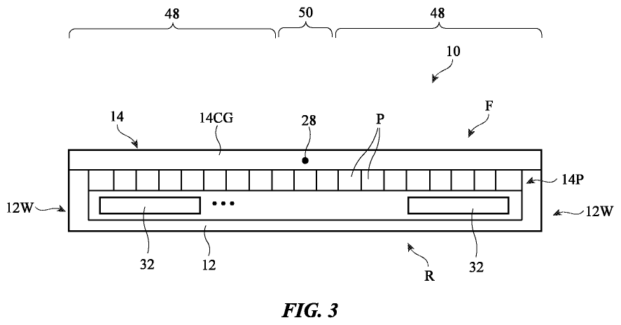

FIG. 3 is a cross-sectional side view of an illustrative foldable electronic device. Device 10 of FIG. 3 may bend about bend axis 28. Bend axis 28 may be aligned with display cover layer 14CG or other structures in device 10. For example, bend axis 28 may pass through a portion of display cover layer 14CG or may be located above or below layer 14CG.

As shown in FIG. 3, display 14 includes an array of pixels P forming display panel 14P under an inwardly facing surface of display cover layer 14CG. Display panel 14P may be, for example, a flexible organic light-emitting diode display or a microLED display in which light-emitting pixels are formed on a flexible substrate layer (e.g., a flexible layer of polyimide or a sheet of other flexible polymer). Flexible support layer(s) for display 14 may also be formed from flexible glass, flexible metal, and/or other flexible structures.

Display cover layer 14CG may be formed from polymer, glass, crystalline materials such as sapphire, other materials, and/or combinations of these materials. To enhance flexibility, a portion of layer 14CG that overlaps bend axis 28 may be locally thinned (e.g., this portion may be thinned relative to portions of layer 14CG that do not overlap bend axis 28). The thickness of layer 14CG (e.g., the non-thinned portions of layer 14CG) may be 50-200 microns, 70-150 microns, 100-200 microns, 100-600 microns, at least 100 microns, at least 200 microns, less than 600 microns, less than 400 microns, less than 250 microns, less than 150 microns, less than 100 microns, at least 50 microns, or other suitable thickness.

In the example of FIG. 3, housing 12 has portions that form a rear housing wall on rear face R of device 10 and has portions forming sidewalls 12W of device 10. The rear housing wall of housing 12 may form a support layer for components in device 10. Housing 12 may also have one or more interior supporting layers (e.g., frame structures such as an optional midplate, etc.). These interior supporting layers and the rear housing wall may have first and second portions that are coupled to opposing sides of hinge 30 or may be sufficiently flexible to bend around bend axis 28.

Electrical components 32 may be mounted in the interior of device 10 (e.g., between display 14 and the rear of housing 12. Components 32 may include circuitry of the type shown in FIG. 1 (e.g., control circuitry 20, communications circuitry 22, input-output devices 24, batteries, etc.). Display 14 may be mounted on front face F of device 10. When device 10 is folded about axis 28, display cover layer 14CG, display panel 14P, and the other structures of device 10 that overlap bend axis 28 may flex and bend to accommodate folding.

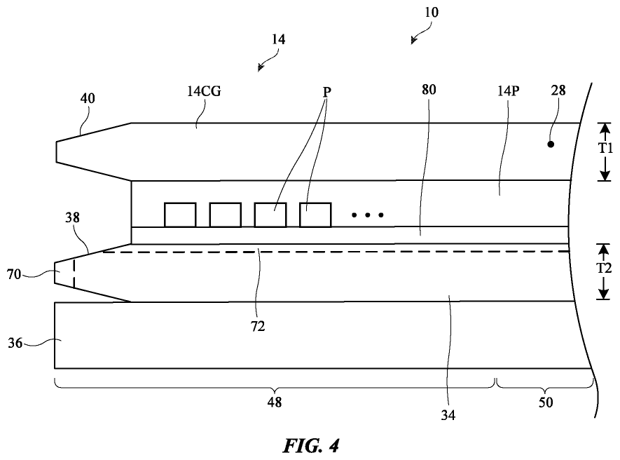

FIG. 4 is a side view of device 10 showing illustrative layers of display 14. As shown in FIG. 4, display 14 may include display layer 14P with an array of pixels P. Pixels P may be located on a display substrate such as substrate 80. Substrate 80 may be a layer of polyimide or other suitable polymer. Pixels P may display images through display cover layer 14CG. Display cover layer 14CG may overlap and protect display layer 14P.

Display layer 14P may be supported by one or more backing layers such as backing layer 34 and backing layer 36. Backing layer 36 may be a thin metal plate that is solid in non-bending regions 48 and that has slots or other openings in bend region 50 to enhance flexibility along bend axis 28. In other arrangements, backing layer 36 may be formed from glass, sapphire, diamond, zirconia, carbon fiber, titanium, polymer, and/or other suitable materials.

If desired, one or more additional backing layers such as backing layer 34 may be interposed between backing layer 36 (sometimes referred to as a backplate or metal backplate) and substrate 80 of display layer 14P. The elastic modulus of backing layer 34 may be, for example, between 50 GPa and 300 GPa or other suitable elastic modulus. Backing layer 34 may be formed from glass (e.g., aluminosilicate glass, soda lime glass, borosilicate glass, lithium, aluminosilicate, etc.), sapphire, diamond, zirconia, fiber-reinforced materials (fiberglass, carbon fiber, etc.), titanium, polymer, electroactive polymers, non-Newtonian materials, shape memory alloys, and/or other suitable materials. Arrangements in which backing layer 34 is formed from glass are sometimes described herein as an example. Glass may have a higher modulus of elasticity than polyimide and polyethylene terephthalate and may therefore provide better stiffness than polymers behind display layer 14P, while remaining sufficiently elastic to accommodate folding and unfolding of device 10. If desired, non-bending regions 48 of backing layer 34 may have a higher stiffness or elastic modulus than bend region 50. This may be achieved through variations in materials, thickness, fiber orientation, embedded structures, and/or other variations in bend region 50 relative to non-bending region 48.

Backing layer 34 may have a uniform thickness across non-bending regions 48 and bend region 50 or backing layer 34 may have a variable thickness (e.g., a reduced thickness in bend region 50 relative to non-bending regions 48). The thickness T1 of layer 14CG (e.g., the non-thinned portions of layer 14CG) may be 30-50 microns, 50-200 microns, 70-150 microns, 100-200 microns, 100-600 microns, at least 100 microns, at least 200 microns, less than 600 microns, less than 400 microns, less than 250 microns, less than 150 microns, less than 100 microns, at least 50 microns, or other suitable thickness. The thickness T2 of layer 34 may be 30-90 microns, 50-150 microns, 100-200 microns, 300-400 microns, less than 400 microns, greater than 400 microns, or other suitable thickness. Thickness T2 may be greater than thickness T1, if desired. As shown in FIG. 4, cover glass 14CG may have a chamfered edge such as chamfered edge 40, and backing layer 34 may have a chamfered edge such as chamfered edge 38. Chamfered edges 40 and 38 may help avoid sharp corners in the glass where stress would otherwise tend to concentrate.

If desired, backing layer 34 may be strengthened through ion exchange to create compressive stress in the glass. For example, the compressive stress of backing layer 34 may be between 400 MPa and 500 MPa, between 350 MPa and 550 MPa, greater than 400 MPa, less than 500 MPa, or other suitable compressive stress. In some arrangements, a localized ion exchange process may be performed on backing layer 34 which may result in non-uniform ion concentrations in different areas of layer 34. For example, glass layer 34 may undergo a first ion exchange process which results in chemically strengthened surface 72. If the outer edges of glass layer 34 are trimmed after the first ion exchange process, this may result in exposed tension in peripheral edge surface 70. To compensate for this exposed tension, a localized ion exchange process may be performed on the outer peripheral edges of layer 34 such as surface 70. This may include printing a potassium nitrate slurry on edge surface 70 and performing ion exchange locally on edge surface 70. Due to this localized ion exchange process, layer 34 may have a different ion concentration and compressive stress in top surface 72 relative to the ion concentration and compressive stress in edge surface 70.

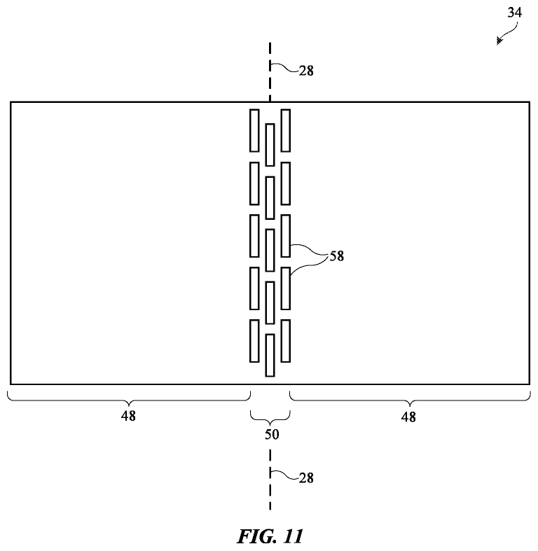

By replacing polymer backing layers behind display substrate 80 with layers having higher moduli of elasticity such as backing layer 34, the strength of display 14 may be increased while still allowing display 14 to bend and flex in region 50. If desired, layer 34 may also replace polymer substrate 80 on which pixels P are formed. For example, glass such as glass backing layer 34 may be used as a substrate on which pixels P are directly formed (e.g., organic light-emitting diodes may be grown or otherwise directly formed on a glass substrate such as backing layer 34). Arrangements in which backing layer 34 replaces metal backplate 36 may also be used, if desired. This type of arrangement is described in more detail in connection with FIG. 11.

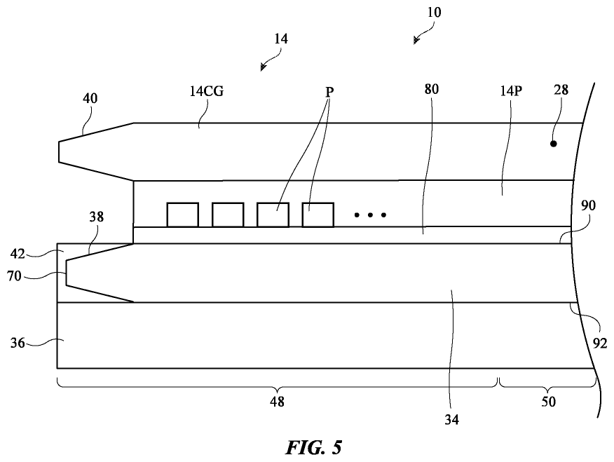

FIG. 5 shows an example in which a coating such as coating 42 is applied to outer edge surface 70 of glass layer 34. Coating 42 may be a resin (e.g., an ultraviolet light cured resin, a thermally cured resin, an optically cured resin, etc.) that covers edge surface 70 (including chamfered edges 38) of layer 34. Coating 42 may wrap partially or entirely around the perimeter of backing layer 34. Once cured, a laser or other cutting tool may be used to trim off outer portions of coating 42 so that layer 34 has the desired shape and size. For example, coating 42 may be trimmed to align with the peripheral edge surface of backing layer 36, as shown in FIG. 5.

The example of FIG. 5 in which coating 42 is only applied to the outer peripheral edge surface 70 of backing layer 34 is merely illustrative. If desired, coating 42 may also coat upper surface 90 and opposing lower surface 92 of backing layer 34.

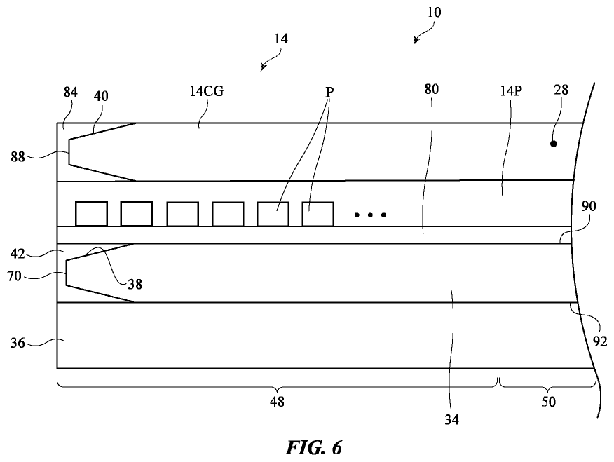

FIG. 6 shows an example in which a coating such as coating 84 has also been applied to outer edge surface 88 of cover glass 14CG. Coating 84 may be a resin (e.g., an ultraviolet light cured resin, a thermally cured resin, an optically cured resin, etc.) that covers edge surface 88 (including chamfered edges 40) of cover glass 14CG. Coating 84 may wrap partially or entirely around the perimeter of cover glass 14CG. Once cured, a laser or other cutting tool may be used to trim off outer portions of coating 84 so that cover glass 14CG has the desired shape and size. For example, coating 84 may be trimmed to align with the edge of coating 42 of backing layer 34 and the peripheral edge surface of backing layer 36.

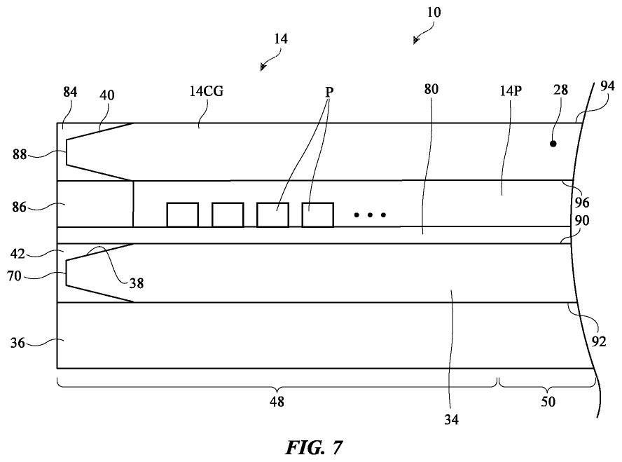

In some arrangements, coating 84 may be optically transparent so that light from pixels P can pass through coating 84. This allows pixels P in display layer 14P to extend to the outermost edges of device 10, as shown in the example of FIG. 6. This is merely illustrative, however. If desired, the space between coatings 84 and 42 may be filled by a support structure to make the edges of device 10 more robust. This type of arrangement is illustrated in FIG. 7.

As shown in FIG. 7, coating 84 may be applied to outer peripheral edge 88 of cover glass 14CG, and coating 42 may be applied to outer surface 70 of backing layer 34. The gap between coatings 42 and 84 may be filled by a support structure such as support structure 86. Support structure 86 may be formed from metal, polymer, or other suitable material. In some arrangements, support structure 86 may be a molded polymer (e.g., a low pressure injection molded polymer or other suitable polymer).

The examples of FIGS. 6 and 7 in which coating 42 is only applied to the outer peripheral edge surface 70 of backing layer 34 and coating 84 is only applied to outer peripheral edge surface 88 of cover glass 14CG are merely illustrative. If desired, coating 42 may also coat upper surface 90 and opposing lower surface 92 of backing layer 34. Coating 84 may also coat upper surface 94 and opposing lower surface 96 of cover layer 14CG, if desired.

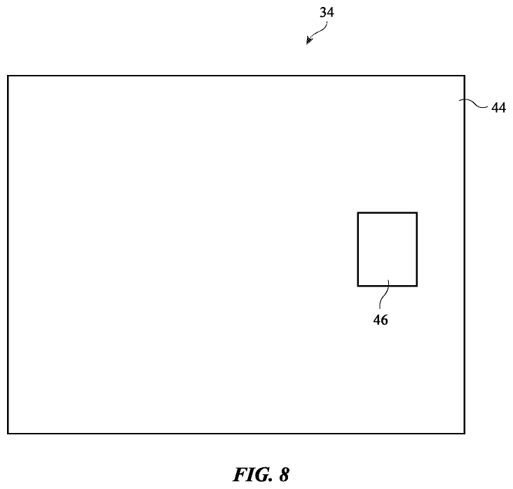

FIG. 8 is a top view of backing layer 34 showing how windows such as light-transmitting window 46 may be formed in backing layer 34. Because backing layer 34 is behind display layer 14P, backing layer need not be transparent. This may allow for opaque polymers, metals, and/or other materials with the appropriate elasticity modulus to be used behind display layer 14P, without obscuring light from the display. For example, backing layer 34 may be an opaque film with transparent inserts that form windows such as window 46.

Optical components that are mounted behind display layer 14P and behind backing layer 34 may be configured to transmit and/or receive light through window 46. For example, one or more optical sensors (e.g., ambient light sensors, visible light cameras, infrared light cameras, and/or any other suitable optical sensors in sensors 16 of FIG. 1) may be mounted in alignment with window 46 and may be configured to detect ambient light through window 46. Light-emitting devices (e.g., infrared light-emitting diodes, visible light-emitting diodes, camera flash components, and/or other suitable light-emitting devices) may be configured to emit light through window 46.

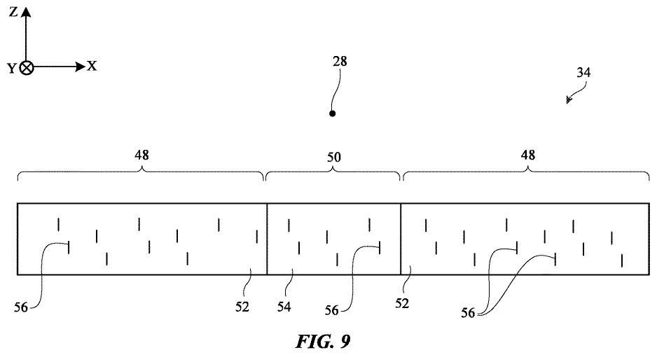

FIG. 9 is a side view of backing layer 34 showing an example in which backing layer 34 is formed from a fiber-reinforced material such as fiberglass, carbon fiber, and/or any other suitable fiber-reinforced material. As shown in FIG. 9, backing layer 34 may include fibers such as glass fibers 56 in a polymer matrix such as polymer 52 and polymer 54. To provide additional stiffness, glass fibers 56 may be oriented vertically (e.g., orthogonal to bend axis 28 and parallel to the Z-axis of FIG. 9), if desired.

Stiffness of backing layer 34 can also be tuned by using different types of polymer matrices for glass fibers 56 in different locations of layer 34. For example, polymer 52 in non-bending regions 48 may be different from polymer 54 in bend region 50. Polymer 52 in non-bending regions 48 may a stiff polymer such as polyimide, acrylic, or any other suitable stiff polymer. Polymer 54 in bend region 50 may be a flexible polymer such as epoxy, polycarbonate, or any other suitable flexible polymer (e.g., a polymer having a lower modulus of elasticity than polymer 52 in non-bending regions 48).

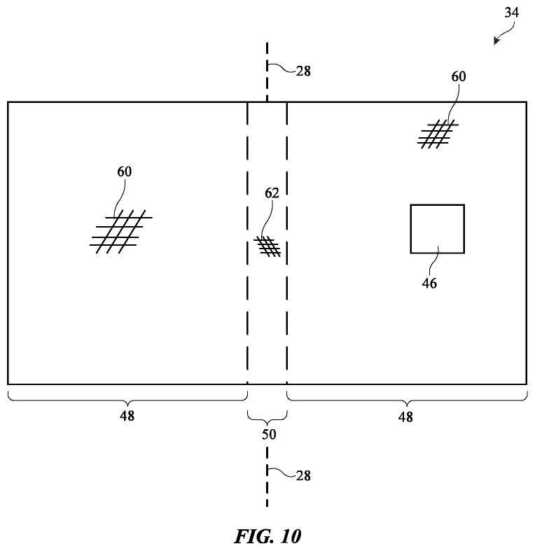

FIG. 10 is a top view of backing layer 34 showing an example in which backing layer 34 is formed from a fiber-reinforced material such as carbon fiber. As shown in FIG. 10, backing layer 34 may include fibers such as carbon fibers 60 and 62. Carbon fibers 60 and 62 may be formed in a plastic resin (e.g., backing layer 34 may be a carbon-fiber reinforced polymer layer), if desired. If desired, carbon fibers 60 in non-bending regions 48 may have a different weave than carbon fibers 62 in bend region 50. For example, carbon fibers 62 in bend region 50 may have a weave that promotes bending along bend axis 28, whereas carbon fibers 60 in non-bending regions 48 may have a weave that is stiffer than the weave of fibers 62.

If desired, carbon fibers may be omitted from certain regions of layer 34 such as light-transmitting window 46. By omitting fibers from window 46, light may be configured to pass through window 46 of layer 34 without obstruction. Window 46 may be formed from the same resin that binds carbon fibers 62 and 60, or window 46 may be filled with other polymer. Arrangements in which window 46 is a cut-out portion of layer 34 that is filled with air may also be used, if desired.

FIG. 11 is a top view of backing layer 34 showing an example in which backing layer 34 includes openings such as openings 58 in bend region 50. Openings 58 may be slits, recesses, holes, and/or other openings in backing layer 34. If desired, backing layer 34 may be formed from solid glass in non-bending regions 48 to provide additional stiffness in regions 48. Openings 58 may be formed in the glass in region 50 to allow layer 34 to bend and flex in region 50. Openings 58 may be through-holes that extend entirely through the thickness of the glass, or openings 58 may be recesses that extend only partway through the thickness of the glass (e.g., from a top surface of the glass and/or from a bottom surface of the glass).

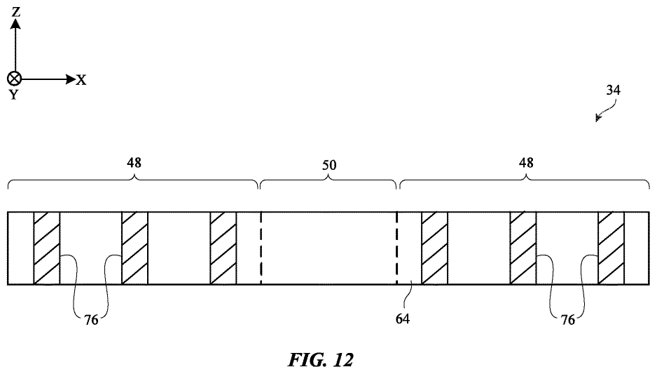

In addition to or instead of using openings 58 to enhance flexibility in region 50, stiffeners may be incorporated into non-bending regions 48 of backing layer 34. This type of arrangement is shown in FIG. 12. FIG. 12 is a side view of backing layer 34 showing an example in which stiffening pillars such as pillars 76 are incorporated into non-bending regions 48 of backing layer 34. Pillars 76 may be elongated rods of material (e.g., metal, glass, plastic, etc.) or other elongated structures formed in a material such as material 64 (e.g., glass, polymer, etc.). The longitudinal axis of each pillar 76 may be perpendicular to bend axis 28 and parallel to the Z-axis of FIG. 12. Pillars 76 may be absent from bend region 50 to allow bend region 50 to bend and flex.

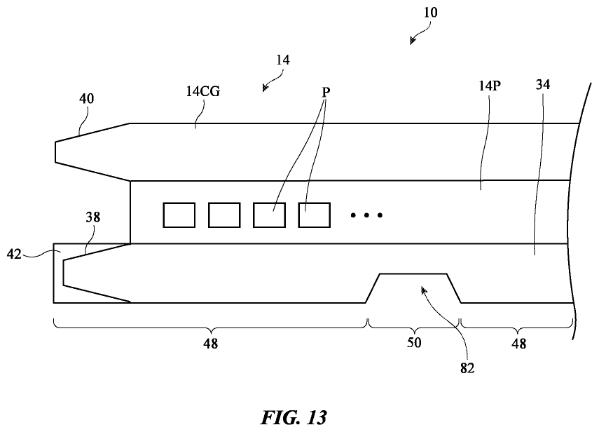

FIG. 13 is a side view of device 10 showing how backing layer 34 may replace other backing layers in display 14 such as a metal backplate (e.g., backing layer 36 of FIG. 4). Backing layer 34 may be interposed between display panel 34 and a rear housing wall of housing 12. To provide sufficient stiffness without a metal backplate, backing layer 34 may be thicker in non-bending regions 48 than in bend region 50. For example, the thickness of backing layer 34 in non-bending regions 48 may be 90-200 microns or other suitable thickness. A recess such as recess 82 may be formed in bend region 50 of backing layer 34 to provide sufficient flexibility in region 50.

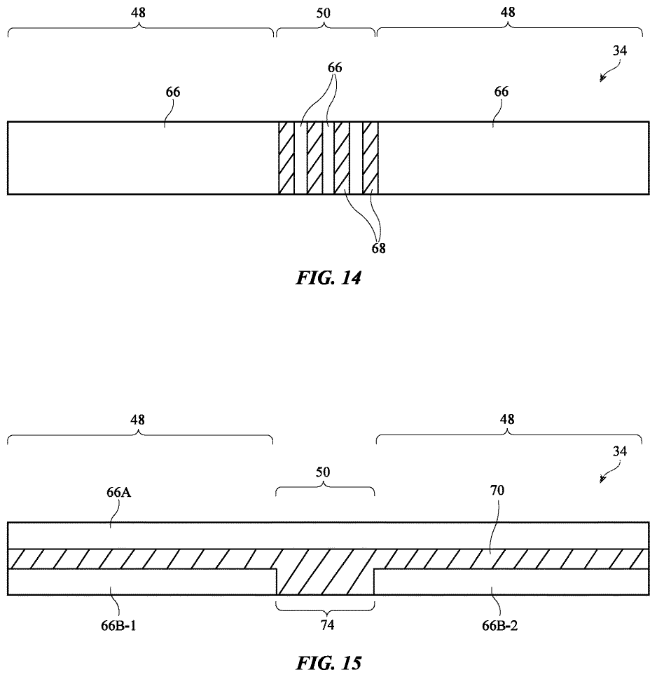

FIGS. 14 and 15 are side views of backing layer 34 showing illustrative examples in which backing layer 34 is formed from a combination of glass and polymer layers. In the example of FIG. 14, backing layer 34 includes a layer of glass 66 that is solid in non-bending regions 48 and that is interleaved with polymer layers 68 in bend region 50. The gaps between glass portions 66 (e.g., gaps that are filled with polymer 68) in region 50 may permit bending along bend axis 28.

In the example of FIG. 15, backing layer 34 includes a first layer of glass such as upper layer 66A that extends with uniform thickness across non-bending regions 48 and bend region 50. Additional glass layers such as lower glass layer 66B-1 and lower glass layer 66B-2 may be laminated to upper glass layer 66A using a polymer such as polymer 70. Lower glass layer 66B-1 and lower glass layer 66B-2 may be separated by a gap in region 50 such as gap 74. Gap 74 may help enhance flexibility of backing layer 34 in region 50. If desired, polymer 70 may fill gap 74.

Device 10 may be operated in a system that uses personally identifiable information. It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing is merely illustrative and various modifications can be made to the described embodiments. The foregoing embodiments may be implemented individually or in any combination.

What is claimed is:

1. An electronic device, comprising:
an array of pixels formed on a substrate;
a display cover glass overlapping the array of pixels; and
a glass backing layer configured to support the substrate, wherein the substrate is interposed between the display cover glass and the glass backing layer, and wherein the substrate, the display cover glass, and the glass backing layer are configured to bend about a bend axis.

2. The electronic device defined in claim 1 wherein the glass backing layer exhibits a compressive stress of at least 400 MPa.

3. The electronic device defined in claim 2 wherein the glass backing layer has first and second opposing surfaces joined by a peripheral edge surface, wherein the first surface has a different amount of compressive stress than the peripheral edge surface.

4. The electronic device defined in claim 1 further comprising a metal backplate configured to support the glass backing layer, wherein the glass backing layer is interposed between the substrate and the metal backplate.

5. The electronic device defined in claim 4 further comprising a coating on a peripheral edge surface of the glass backing layer, wherein the coating has a first edge and the metal backplate has a second edge that is aligned with the first edge.

6. The electronic device defined in claim 5 further comprising an additional coating on an additional peripheral edge surface of the display cover glass, wherein the additional coating has a third edge aligned with the first edge.

7. The electronic device defined in claim 1 wherein the glass backing layer comprises slits that overlap the bend axis.

8. The electronic device defined in claim 1 wherein the glass backing layer has a reduced thickness in a region that overlaps the bend axis relative to other regions of the glass backing layer.

9. The electronic device defined in claim 1 wherein the glass backing layer comprises glass portions in the bend region separated by gaps that are filled with polymer.

10. The electronic device defined in claim 1 wherein the glass backing layer comprises:
a first glass layer with uniform thickness that extends across the bend axis;
second and third glass layers overlapping the first glass layer and separated by a gap that overlaps the bend axis; and
a polymer material that fills the gap and that is interposed between the first glass layer and the second glass layer and between the first glass layer and the third glass layer.

11. An electronic device, comprising:
a cover glass configured to fold along a bend axis;
an array of pixels configured to display images through the cover glass; and
a backing layer configured to support the array of pixels, wherein the array of pixels is interposed between the cover glass and the backing layer, wherein the backing layer comprises first and second regions separated by a bend region aligned with the bend axis, and wherein the first and second regions are stiffer than the bend region.

12. The electronic device defined in claim 11 wherein the backing layer comprises a first type of polymer in the first and second regions and a second type of polymer in the bend region, and wherein the first type of polymer is different from the second type of polymer.

13. The electronic device defined in claim 12 further comprising glass fibers embedded in the first and second types of polymer, wherein the glass fibers are perpendicular to the bend axis.

14. The electronic device defined in claim 11 wherein the backing layer comprises carbon fiber having a first weave in the first and second regions and a second weave in the bend region, and wherein the first weave is different from the second weave.

15. The electronic device defined in claim 11 wherein the backing layer comprises a polymer material with embedded pillars in the first and second regions that extend across a thickness of the backing layer and wherein the embedded pillars are absent from the bend region.

16. The electronic device defined in claim 11 wherein the backing layer comprises a light-transmitting window.

17. An electronic device, comprising:
a foldable glass layer configured to bend along a bend axis;
a pixel array configured to display images through the foldable glass layer; and
a backing layer configured to support the pixel array, wherein the pixel array is interposed between the foldable glass layer and the backing layer and wherein the backing layer has an elastic modulus ranging from 50 GPa to 300 GPa.

18. The electronic device defined in claim 17 wherein the backing layer comprises an opaque film with a light transmitting window.

19. The electronic device defined in claim 17 wherein the backing layer comprises a material selected from the group consisting of: glass, sapphire, diamond, zirconia, fiberglass, carbon fiber, titanium, electroactive polymer, non-Newtonian material, and shape memory alloy.

20. The electronic device defined in claim 17 wherein the backing layer comprises a uniform thickness glass layer having a greater thickness than the foldable glass layer.
